(19) United States
(12) Patent Application Publication
(10) Pub. No.: US 2010/0189898 A1
(43) Pub. Date: Jul. 29, 2010

(54) MANUFACTURING OF ADDUCT FREE ALKALINE-EARTH METAL Cp COMPLEXES

(75) Inventors: Zhiwen WAN, Plano, TX (US); Ashutosh Misra, Plano, TX (US)

Correspondence Address: AIR LIQUIDE USA LLC;Intellectual Property, 2700 POST OAK BOULEVARD, SUITE 1800, HOUSTON, TX, 77056, US

(73) Assignees: Zhiwen Wan, Plano, TX (US); Ashutosh Misra, Plano, TX (US); Air Liquide Electronics U.S. LP

(21) Appl. No.: 12/691,981

(22) Filed: Jan. 22, 2010

Related U.S. Application Data
(60) Provisional application No. 61/146,515, filed on Jan. 22, 2009.

(51) Int. Cl. C23C 16/18; C07F 17/00; C23C 16/44

(52) U.S. Cl. 427/248.1; 549/209

(57) ABSTRACT

Methods and compositions for the deposition of a metal containing film on a substrate. The film is deposited with a substantially adduct free precursor which is prepared by a process to remove the adduct from an adducted starting material.

### CROSS-REFERENCE TO RELATED APPLICATIONS

The present application claims the benefit of U.S. Provisional Application Ser. No. 61/146,515 filed Jan. 22, 2009, herein incorporated by reference in its entirety for all purposes.

### BACKGROUND

1. Field of the Invention

This invention relates generally to compositions, methods and apparatus used for use in the manufacture of semiconductor, photovoltaic, LCF-TFT, or flat panel type devices. More specifically, the invention relates to a method of preparing a metal containing precursor.

2. Background of the Invention

Steric metallocenes of alkaline earth metals are promising precursors for thin film deposition in superconductor and semiconductor fabrication due to their high volatilities. The metallocenes have thus far been synthesized with substituted cyclopentadienyl lithium or sodium salt (LiCp* or NaCp*) in a polar solvent like THF and metal halide due to high solubility of these salts in polar solvents. The resulting metallocenes are normally then adducted with THF by complexation with the oxygen atom in THF molecule. The solvent molecules coordinating to metallocenes are called “adducts”. The common adducted alkaline earth metal complexes are Sr(Cp*)₂(THF)₂ and Ba(Cp*)₂(THF)₂ where the adduct in Sr(Cp*)₂(THF)₂ and Ba(Cp*)₂(THF)₂ is THF, and where Cp* signifies a cyclopentadienyl group substituted with alkyl groups (such as methyl, isopropyl, or tert-butyl).

Besides adducts containing oxygen, any molecule which has at least one lone pair of electrons can act as an adduct to coordinate with metallocenes, such as pyridine (which contains nitrogen), etc. Many other organometallics besides metallocenes can also form an adduct complex after being synthesized from polar solvents. Normally it is found that adducted forms of organometallic compounds are more stable versus the non-adducted forms.

The coordination bond between adduct and metal ions is typically the weakest bond in the metal complex. When the adducted complex is heated up, the weak-bonded adduct will dissociate. After cooling, the adduct and the complex will combine again to form an adducted complex.

When adducted complexes are used in a thin film deposition process, such as a CVD, ALD or MOCVD process, adducted complexes are introduced into the deposition chamber as vapor at a raised temperature. In this case, the adducted complex may complicate the CVD reaction, due to the fact that the adduct will be disassociating from the complex. The dissociation of adduct may cause energy input to the process, thereby causing loss of control of the reaction and a non-uniform delivery of the complex. An adduct-free complex would provide better process control and uniform vapor pressure.

One method to make adduct-free metallocenes, involves applying a higher temperature to break the bond between adduct and metal ion. At the same time, the free adduct could then be removed. For example, the strontium metallocenes Sr(Cp*)₂(THF)₂ at higher temperature will release THF and form equilibrium as below.

Sr(Cp*)₂(THF)₂ [symbol] THF+Sr(Cp*)₂(THF) [symbol] Sr(Cp*)2+THF

However, thermal studies of Sr(Cp*)₂(THF)₂ have found that THF is released starting at 140° C. but complete THF removal does not occur until a temperature of about 260° C. is reached. However, it was found that at this temperature, the strontium metallocene sublimed, and therefore the overall yield of the adduct free metallocene was very low.

Consequently, there exists a need for methods for providing metal containing precursors that are substantially free of adduct.

### BRIEF SUMMARY

Embodiments of the present invention provide novel methods and compositions useful for the deposition of a film on a substrate. In general, the disclosed compositions and methods utilize a metal containing precursor. In an embodiment, a method for providing a metal containing precursor substantially free of any adduct comprises providing an adducted metal containing precursor of the general formula:

M(YₙCp)ₘ(X)ₐ(A)ₛ (I)

wherein M is chosen from among the alkaline earth metals; Cp is the cyclopentadienyl ligand; Y is a C1-C6 alkyl group; X is a ligand selected from among a C1-C6 alkyl group substituted cyclopentadienyl ligand, a dialkyl amide, an alkoxide, a halogen, and tetramethylheptadionate; A is a Lewis base adduct; and n is an integer inclusively between 1 and 5, m and a are both integers inclusively between 0 and 2, and the sum of m and n is equal to 2, s is an integer, preferably 1 or 2, but potentially any integer. At least one solvent is introduced to the precursor to form a solvent and precursor mixture. The solvent and precursor mixture is distilled to remove the adduct from the precursor, and a substantially adduct free precursor is received, where the substantially adduct free precursor is of the general formula:

M(YₙCp)ₘ(X)ₐ (II).

In an embodiment, a method for depositing an alkaline earth metal containing film on a substrate comprises providing a reactor with at least one substrate disposed in the reactor. An adducted metal containing precursor is provided, where the adducted metal containing precursor is of the general formula:

M(YₙCp)ₘ(X)ₐ(A)ₛ (I)

wherein M is chosen from among the alkaline earth metals; Cp is the cyclopentadienyl ligand; Y is a C1-C6 alkyl group; X is a ligand selected from among a C1-C6 alkyl group substituted cyclopentadienyl ligand, a dialkyl amide, an alkoxide, a halogen, and tetramethylheptadionate; A is a Lewis base adduct; and n is an integer inclusively between 1 and 5, m and a are both integers inclusively between 0 and 2, and the sum of m and n is equal to 2, s is an integer, preferably 1 or 2, but potentially any integer. At least one solvent is introduced to the precursor to form a solvent and precursor mixture. The solvent and precursor mixture is distilled to remove the adduct from the precursor, and a substantially adduct free precursor is received, where the substantially adduct free precursor is of the general formula:

M(YₙCp)ₘ(X)ₐ (II).

The substantially adduct free precursor is introduced into the reactor. The reactor is maintained at a temperature of at least about 100° C., and the substantially adduct free precursor is contacted with the substrate to form a metal-containing film.

Other embodiments of the current invention may include, without limitation, one or more of the following features:
the solvent and precursor mixture is purified after the distillation step by either a vacuum distillation step or a sublimination step;
the solvent and precursor mixture has a ratio of solvent to precursor of at least about 10:1, preferably of at least about 5:1, or preferably of at least about 3:1;
the solvent has a boiling point greater than that of the adduct, and less that that of the substantially adduct free precursor;
the solvent is one of: toluene; mesitylene; phenetol; octane; xylene; ethylbenzene; propylbenzene; ethyltoluene; ethoxybenzene; pyridine; and mixtures thereof;
the Lewis base adduct is one of: tetrahydrofuran; dioxane; 1,2-diethoxyethane; 1,2-dimethoxyethane; dimethyl ether; diethyl ether and tetrahydropyranyl;
the distilling step is performed at about atmospheric pressure;
the alkaline earth metal is either strontium or barium;
the adducted metal containing precursor is one of: Sr(iPr₃Cp)₂(THF);
   Sr(iPr₃Cp)₂(THF)₂; Sr(iPr₃Cp)₂(DME); Sr(iPr₃Cp)₂(DME)₂;
   Sr(iPr₃Cp)₂(diethylether); Sr(iPr₃Cp)₂(diethylether)₂;
   Sr(tBu₃Cp)₂(THF); Sr(tBu₃Cp)₂(THF)₂; Sr(tBu₃Cp)₂(DME);
   Sr(tBu₃Cp)₂(DME)₂; Sr(tBu₃Cp)₂(diethylether); and
   Sr(tBu₃Cp)₂(diethylether)₂; Ba(iPr₃Cp)₂; Ba(iPr₃Cp)₂(THF);
   Ba(iPr₃Cp)₂(THF)₂; Ba(iPr₃Cp)₂(DME); Ba(iPr₃Cp)₂(DME)₂;
   Ba(iPr₃Cp)₂(diethylether); Ba(iPr₃Cp)₂(diethylether)₂; Ba(tBu₃Cp)₂;
   Ba(tBu₃Cp)₂(THF); Ba(tBu₃Cp)₂(THF)₂; Ba(tBu₃Cp)₂(DME);
   Ba(tBu₃Cp)₂(DME)₂; Ba(tBu₃Cp)₂(diethylether);
   Ba(tBu₃Cp)₂(diethylether)₂; Sr(TMS₂N)₂(THF)₂; Sr(TMS₂N)₂(DME)₂;
   Sr(Et₂N)₂(THF)₂; Sr(Et₂N)₂(DME)₂; Sr(Me₅Cp)(NTMS)(THF)₂;
   Sr(Me₅Cp)(NTMS)(DME)₂; Sr(iPr₃Cp)(NTMS)(THF)₂;
   Sr(iPr₃Cp)(NTMS)(DME)₂; Sr(tBu₃Cp)(NTMS)(THF)₂;
   Sr(tBu₃Cp)(NTMS)(DME)₂; Sr(Me₅Cp)l(THF)₂; Sr(Me₅Cp)l(DME)₂;
   Sr(iPr₃Cp)l(THF)₂; Sr(iPr₃Cp)l(DME)₂; Sr(tBu₃Cp)l(THF)₂;
   Sr(tBu₃Cp)l(DME)₂; Sr(Me₅Cp)(Et₂N)(THF)₂;
   Sr(Me₅Cp)(Et₂N)(DME)₂; Sr(iPr₃Cp)(Et₂N)(THF)₂;
   Sr(iPr₃Cp)(Et₂N)(DME)₂; Sr(tBu₃Cp)(Et₂N)(THF)₂;
   Sr(tBu₃Cp)(Et₂N)(DME)₂; Sr(iPrO)₂(THF)₂; Sr(iPrO)₂(DME)₂;
   Sr(OMe)₂(THF)₂; Sr(OMe)₂(DME)₂; Sr(Me₅Cp)(OMe)(THF)₂;
   Sr(Me₅Cp)(OMe)(DME)₂; Sr(iPr₃Cp)(OMe)(THF)₂;
   Sr(iPr₃Cp)(OMe)(DME)₂; Sr(tBu₃Cp)(OMe)(THF)₂;
   Sr(tBu₃Cp)(OMe)(DME)₂; Sr(Me₅Cp)(OEt)(THF)₂;
   Sr(Me₅Cp)(OEt)(DME)₂; Sr(iPr₃Cp)(OEt)(THF)₂;
   Sr(iPr₃Cp)(OEt)(DME)₂; Sr(tBu₃Cp)(OEt)(THF)₂;
   Sr(tBu₃Cp)(OEt)(DME)₂; Ba(TMS₂N)₂(THF)₂; Ba(TMS₂N)₂(DME)₂;
   Ba(Et₂N)₂(THF)₂; Ba(Et₂N)₂(DME)₂; Ba(Me₅Cp)(NTMS)(THF)₂;
   Ba(Me₅Cp)(NTMS)(DME)₂; Ba(iPr₃Cp)(NTMS)(THF)₂;
   Ba(iPr₃Cp)(NTMS)(DME)₂; Ba(tBu₃Cp)(NTMS)(THF)₂;
   Ba(tBu₃Cp)(NTMS)(DME)₂; Ba(Me₅Cp)l(THF)₂; Ba(Me₅Cp)l(DME)₂;
   Ba(iPr₃Cp)l(THF)₂; Ba(iPr₃Cp)l(DME)₂; Ba(tBu₃Cp)l(THF)₂;
   Ba(tBu₃Cp)l(DME)₂; Ba(Me₅Cp)(Et₂N)(THF)₂;
   Ba(Me₅Cp)(Et₂N)(DME)₂; Ba(iPr₃Cp)(Et₂N)(THF)₂;
   Ba(iPr₃Cp)(Et₂N)(DME)₂; Ba(tBu₃Cp)(Et₂N)(THF)₂;
   Ba(tBu₃Cp)(Et₂N)(DME)₂; Ba(iPrO)₂(THF)₂; Ba(iPrO)₂(DME)₂;
   Ba(OMe)₂(THF)₂, Ba(OMe)₂(DME)₂; Ba(Me₅Cp)(OMe)(THF)₂;
   Ba(Me₅Cp)(OMe)(DME)₂; Ba(iPr₃Cp)(OMe)(THF)₂;
   Ba(iPr₃Cp)(OMe)(DME)₂; Ba(tBu₃Cp)(OMe)(THF)₂;
   Ba(tBu₃Cp)(OMe)(DME)₂; Ba(Me₅Cp)(OEt)(THF)₂₁
   Ba(Me₅Cp)(OEt)(DME)₂; Ba(iPr₃Cp)(OEt)(THF)₂;
   Ba(iPr₃Cp)(OEt)(DME)₂; Ba(tBu₃Cp)(OEt)(THF)₂; and
   Ba(tBu₃Cp)(OEt)(DME)₂.

The foregoing has outlined rather broadly the features and technical advantages of the present invention in order that the detailed description of the invention that follows may be better understood. Additional features and advantages of the invention will be described hereinafter that form the subject of the claims of the invention. It should be appreciated by those skilled in the art that the conception and the specific embodiments disclosed may be readily utilized as a basis for modifying or designing other structures for carrying out the same purposes of the present invention. It should also be realized by those skilled in the art that such equivalent constructions do not depart from the spirit and scope of the invention as set forth in the appended claims.

### Notation and Nomenclature

Certain terms are used throughout the following description and claims to refer to various components and constituents. This document does not intend to distinguish between components that differ in name but not function.

As used herein, the term “alkyl group” refers to saturated functional groups containing exclusively carbon and hydrogen atoms. Further, the term “alkyl group” may refer to linear, branched, or cyclic alkyl groups. Examples of linear alkyl groups include without limitation, methyl groups, ethyl groups, propyl groups, butyl groups, etc. Examples of branched alkyls groups include without limitation, t-butyl. Examples of cyclic alkyl groups include without limitation, cyclopropyl groups, cyclopentyl groups, cyclohexyl groups, etc.

As used herein, the abbreviation, “Me,” refers to a methyl group; the abbreviation, “Et,” refers to an ethyl group; the abbreviation, “tBu,” refers to a tertiary butyl group; the abbreviation “iPr”, refers to an isopropyl group; the abbreviation “Cp” refers to a cyclopentadienyl group; the abbreviation “THD” refers to tetramethylheptadionate; the abbreviation “TMS” refers to trimethylsilyl; the abbreviation “THF” refers to tetrahydrofuran; the abbreviation “DME” refers to 1,2-dimethoxyethane; and the abbreviation “Cp*” refers to a substituted cyclopentadienyl ligand.

As used herein, elements form the standard periodic table of elements may be referred to according to their common abbreviation. For instance, “Sr” should be recognized to refer to the element strontium, “Ba” should be recognized to refer to the element barium, “N” should be recognized to refer to the element nitrogen, etc.

As used herein, the term “independently” when used in the context of describing R groups (or other variable equivalents to R groups) should be understood to denote that the subject R group is not only independently selected relative to other R groups bearing the same or different subscripts or superscripts, but is also independently selected relative to any additional species of that same R group. For example in the formula MR¹ₓ(NR²R³)₍₄₋ₓ₎, where x is 2 or 3, the two or three R¹ groups may, but need not be identical to each other or to R² or to R³. Further, it should be understood that unless specifically stated otherwise, values of R groups are independent of each other when used in different formulas.

### BRIEF DESCRIPTION OF THE DRAWINGS

For a further understanding of the nature and objects for the present invention, reference should be made to the following detailed description, taken in conjunction with the accompanying drawings, in which like elements are given the same or analogous reference numbers and wherein:

FIG. 1 illustrates an NMR analysis comparing an adducted metal containing precursor, and a metal containing precursor substantially free of adduct;

FIG. 2 illustrates a second NMR analysis comparing an adducted metal containing precursor, and a metal containing precursor substantially free of adduct; and

FIG. 3 illustrates a third NMR analysis comparing an adducted metal containing precursor, and a metal containing precursor substantially free of adduct.

### DESCRIPTION OF PREFERRED EMBODIMENTS

Embodiments of the present invention provide novel methods and compositions useful for the deposition of a film on a substrate. Methods to prepare a substantially adduct free precursor are provided.

In some embodiments, a method for providing a metal containing precursor substantially free of any adduct comprises providing an adducted metal containing precursor of the general formula:

M(YₙCp)ₘ(X)ₐ(A)ₛ (I)

wherein M is chosen from among the alkaline earth metals; Cp is the cyclopentadienyl ligand; Y is a C1-C6 alkyl group; X is a ligand selected from among a C1-C6 alkyl group substituted cyclopentadienyl ligand, a dialkyl amide, an alkoxide, a halogen, and tetramethylheptadionate; A is a Lewis base adduct; and n is an integer inclusively between 1 and 5, m and a are both integers inclusively between 0 and 2, and the sum of m and n is equal to 2 and s is an integer, preferably 1 or 2. At least one solvent is introduced to the precursor to form a solvent and precursor mixture. The solvent and precursor mixture is distilled to remove the adduct from the precursor, and a substantially adduct free precursor is received, where the substantially adduct free precursor is of the general formula:

M(YₙCp)ₘ(X)ₐ (II).

In some embodiments, the adducted metal containing precursor may be one of the following: Sr(iPr₃Cp)₂(THF); Sr(iPr₃Cp)₂(THF)₂; Sr(iPr₃Cp)₂(DME);
Sr(iPr₃Cp)₂(DME)₂; Sr(iPr₃Cp)₂(diethylether); Sr(iPr₃Cp)₂(diethylether)₂;
Sr(tBu₃Cp)₂(THF); Sr(tBu₃Cp)₂(THF)₂; Sr(tBu₃Cp)₂(DME); Sr(tBu₃Cp)₂(DME)₂;
Sr(tBu₃Cp)₂(diethylether); Sr(tBu₃Cp)₂(diethylether)₂; Ba(iPr₃Cp)₂;
Ba(iPr₃Cp)₂(THF); Ba(iPr₃Cp)₂(THF)₂; Ba(iPr₃Cp)₂(DME); Ba(iPr₃Cp)₂(DME)₂;
Ba(iPr₃Cp)₂(diethylether); Ba(iPr₃Cp)₂(diethylether)₂; Ba(tBu₃Cp)₂;
Ba(tBu₃Cp)₂(THF); Ba(tBu₃Cp)₂(THF)₂; Ba(tBu₃Cp)₂(DME); Ba(tBu₃Cp)₂(DME)₂;
Ba(tBu₃Cp)₂(diethylether); and Ba(tBu₃Cp)₂(diethylether)₂; Sr(TMS₂N)₂(THF)₂;
Sr(TMS₂N)₂(DME)₂; Sr(Et₂N)₂(THF)₂; Sr(Et₂N)₂(DME)₂; Sr(Me₅Cp)(NTMS)(THF)₂;
Sr(Me₅Cp)(NTMS)(DME)₂; Sr(iPr₃Cp)(NTMS)(THF)₂; Sr(iPr₃Cp)(NTMS)(DME)₂;
Sr(tBu₃Cp)(NTMS)(THF)₂; Sr(tBu₃Cp)(NTMS)(DME)₂; Sr(MeₛCp)l(THF)₂;
Sr(Me₅Cp)l(DME)₂; Sr(iPr₃Cp)l(THF)₂; Sr(iPr₃Cp)l(DME)₂; Sr(tBu₃Cp)l(THF)₂;
Sr(tBu₃Cp)l(DME)₂; Sr(Me₅Cp)(Et₂N)(THF)₂; Sr(Me₅Cp)(Et₂N)(DME)₂;
Sr(iPr₃Cp)(Et₂N)(THF)₂; Sr(iPr₃Cp)(Et₂N)(DME)₂; Sr(tBu₃Cp)(Et₂N)(THF)₂;
Sr(tBu₃Cp)(Et₂N)(DME)₂; Sr(iPrO)₂(THF)₂; Sr(iPrO)₂(DME)₂; Sr(OMe)₂(THF)₂;
Sr(OMe)₂(DME)₂; Sr(Me₅Cp)(OMe)(THF)₂; Sr(Me₅Cp)(OMe)(DME)₂;
Sr(iPr₃Cp)(OMe)(THF)₂; Sr(iPr₃Cp)(OMe)(DME)₂; Sr(tBu₃Cp)(OMe)(THF)₂;
Sr(tBu₃Cp)(OMe)(DME)₂; Sr(Me₅Cp)(OEt)(THF)₂; Sr(Me₅Cp)(OEt)(DME)₂;
Sr(iPr₃Cp)(OEt)(THF)₂; Sr(iPr₃Cp)(OEt)(DME)₂; Sr(tBu₃Cp)(OEt)(THF)₂;
Sr(tBu₃Cp)(OEt)(DME)₂; Ba(TMS₂N)₂(THF)₂; Ba(TMS₂N)₂(DME)₂;
Ba(Et₂N)₂(THF)₂; Ba(Et₂N)₂(DME)₂; Ba(Me₅Cp)(NTMS)(THF)₂;
Ba(Me₅Cp)(NTMS)(DME)₂; Ba(iPr₃Cp)(NTMS)(THF)₂; Ba(iPr₃Cp)(NTMS)(DME)₂;
Ba(tBu₃Cp)(NTMS)(THF)₂; Ba(tBu₃Cp)(NTMS)(DME)₂; Ba(Me₅Cp)l(THF)₂;
Ba(Me₅Cp)l(DME)₂; Ba(iPr₃Cp)l(THF)₂; Ba(iPr₃Cp)l(DME)₂; Ba(tBu₃Cp)l(THF)₂;
Ba(tBu₃Cp)l(DME)₂; Ba(Me₅Cp)(Et₂N)(THF)₂; Ba(Me₅Cp)(Et₂N)(DME)₂,
Ba(iPr₃Cp)(Et₂N)(THF)₂; Ba(iPr₃Cp)(Et₂N)(DME)₂; Ba(tBu₃Cp)(Et₂N)(THF)₂;
Ba(tBu₃Cp)(Et₂N)(DME)₂; Ba(iPrO)₂(THF)₂; Ba(iPrO)₂(DME)₂; Ba(OMe)₂(THF)₂;
Ba(OMe)₂(DME)₂; Ba(Me₅Cp)(OMe)(THF)₂; Ba(Me₅Cp)(OMe)(DME)₂;
Ba(iPr₃Cp)(OMe)(THF)₂; Ba(iPr₃Cp)(OMe)(DME)₂; Ba(tBu₃Cp)(OMe)(THF)₂;
Ba(tBu₃Cp)(OMe)(DME)₂; Ba(Me₅Cp)(OEt)(THF)₂; Ba(Me₅Cp)(OEt)(DME)₂;
Ba(iPr₃Cp)(OEt)(THF)₂; Ba(iPr₃Cp)(OEt)(DME)₂; Ba(tBu₃Cp)(OEt)(THF)₂; and
Ba(tBu₃Cp)(OEt)(DME)₂.

In some embodiments, the formation of the solvent and precursor mixture may be performed at a temperature greater than about 100° C. The actual temperature is dependent upon the specific precursor and solvents employed. Likewise, the solvent and precursor mixture may be formed such that there is a greater amount of solvent present than there is precursor. Depending on the specific precursors and solvents employed, the ratio of solvent to precursor may be between 3:1 to 10:1.

In embodiments where the precursor and solvent mixture are distilled to remove the adduct, a short path type distillation at room temperature may be used. A short path distillation is a distillation technique that involves the distillate travelling a short distance. This form of distillation can be done at atmospheric pressure or under reduced pressure. An example would be a distillation process where the distillate travels from one glass bulb to another without the need for a condenser separating the two chambers. This technique is often used for compounds which are unstable at high temperatures or to purify small amounts of compound.

In many embodiments, after the distillation a substantially adduct free precursor is received. In these embodiments, substantially adduct free is understood to mean that the resulting precursor assay is at least about 99% precursor. If further purification is desired, a purifying step of either vacuum distillation or sublimination may be performed on the substantially adduct free precursor. These purification steps typically result in a substantially adduct free precursor where the resulting assay is at least 99.9% precursor. For these purification methods, it is recognized that vacuum distillation is a distillation technique where the pressure above the liquid mixture is reduced to less than its vapor pressure, which leads to evaporation of the most volatile component(s) first. Vacuum distillation can be carried out with or without heating the solution. Sublimation of an element or compound is a transition from the solid to gas phase with no intermediate liquid stage. This technique can be used to purify compounds. As an example, purification of a solid compound that sublimes can be achieved by placing it in a vessel and heated under reduced pressure, which causes the solid to volatilize and condense as a purified compound on a cooled surface, leaving the non-volatile residue impurities behind.

In some embodiments, the solvent is selected depending on the nature of the adduct and the unadducted precursor, such that the boiling point of the solvent is greater than (or about equal) to that of the adduct, but less than that of the unadducted precursor. This is due to the fact that the adduct disassociation requires a certain temperature to occur. Without a solvent being present, the adducted precursor will be evaporated or sublimed during the adduct removal process at raised temperature (e.g. temperature greater than 100° C.). When the solvent is present (provided that the solvent has been selected with respect to boiling point as mentioned above), the disassociation temperature of the adducted precursor will be affected by the solvation effect between the solvent and precursor, which then lowers the overall disassociation temperature as compared to when the solvent is not present. For example, when the adducted metal containing precursor is Sr(Cp*)₂(THF)₂ or Ba(Cp*)₂(THF)₂, the adduct will disassociate at about 140° C. To produce a good quantity of substantially adduct free precursor, a solvent with a boiling point greater (e.g. mesitylene with a by of 167° C.) than this needs to be selected to adequately overcome the energy from the disassociation and to remove the adduct THF. Some examples of suitable solvents, according to at least one embodiment of the current invention, include: toluene; mesitylene; phenetol; octane; xylene; ethylbenzene; propylbenzene; ethyltoluene; ethoxybenzene; pyridine; and mixtures thereof. Some examples of adducts which may be removed form the precursors include: tetrahydrofuran; dioxane; 1,2-diethoxyethane; 1,2-dimethoxyethane; dimethyl ether; diethyl ether and tetrahydropyranyl.

In some embodiments, the substantially adduct free precursor, as described above, may be used to create a thin film on a substrate. The disclosed precursors may be deposited to form a thin film using any deposition methods known to those of skill in the art. Examples of suitable deposition methods include without limitation, conventional CVD, low pressure chemical vapor deposition (LPCVD), plasma enhanced chemical vapor depositions (PECVD), atomic layer deposition (ALD), pulsed chemical vapor deposition (P-CVD), plasma enhanced atomic layer deposition (PE-ALD), metalorganic chemical vapor deposition (MOCVD) or combinations thereof.

In an embodiment, the first precursor is introduced into a reactor in vapor form. The precursor in vapor form may be produced by vaporizing a liquid precursor solution, through a conventional vaporization step such as direct vaporization, distillation, or by bubbling an inert gas (e.g. N₂, He, Ar, etc.) into the precursor solution and providing the inert gas plus precursor mixture as a precursor vapor solution to the reactor. Bubbling with an inert gas may also remove any dissolved oxygen present in the precursor solution.

The reactor may be any enclosure or chamber within a device in which deposition methods take place such as without limitation, a cold-wall type reactor, a hot-wall type reactor, a single-wafer reactor, a multi-wafer reactor, or other types of deposition systems under conditions suitable to cause the precursors to react and form the layers.

Generally, the reactor contains one or more substrates on to which the thin films will be deposited. The one or more substrates may be any suitable substrate used in semiconductor, photovoltaic, flat panel or LCD-TFT device manufacturing. Examples of suitable substrates include without limitation, silicon substrates, silica substrates, silicon nitride substrates, silicon oxy nitride substrates, tungsten substrates, or combinations thereof. Additionally, substrates comprising tungsten or noble metals (e.g. platinum, palladium, rhodium or gold) may be used. The substrate may also have one or more layers of differing materials already deposited upon it from a previous manufacturing step.

In some embodiments, in addition to the first precursor, a reactant gas may also be introduced into the reactor. In some of these embodiments, the reactant gas may be an oxidizing gas such as one of oxygen, ozone, water, hydrogen peroxide, nitric oxide, nitrogen dioxide, radical species of these, as well as mixtures of any two or more of these. In some other of these embodiments, the reactant gas may be a reducing gas such as one of hydrogen, ammonia, a silane (e.g. SiH₄; Si₂H₆; Si₃H₈), SiH₂Me₂; SiH₂Et₂; N(SiH₃)₃; radical species of these, as well as mixtures of any two or more of these.

In some embodiments, and depending on what type of film is desired to be deposited, a second precursor may be introduced into the reactor. The second precursor comprises another metal source, such as copper, praseodymium, manganese, ruthenium, titanium, tantalum, bismuth, zirconium, hafnium, lead, niobium, magnesium, aluminum, lanthanum, or mixtures of these. In embodiments where a second metal containing precursor is utilized, the resultant film deposited on the substrate may contain at least two different metal types.

The first precursor and any optional reactants or precursors may be introduced sequentially (as in ALD) or simultaneously (as in CVD) into the reaction chamber. In some embodiments, the reaction chamber is purged with an inert gas between the introduction of the precursor and the introduction of the reactant. In one embodiment, the reactant and the precursor may be mixed together to form a reactant/precursor mixture, and then introduced to the reactor in mixture form. In some embodiments, the reactant may be treated by a plasma, in order to decompose the reactant into its radical form. In some of these embodiments, the plasma may generally be at a location removed from the reaction chamber, for instance, in a remotely located plasma system. In other embodiments, the plasma may be generated or present within the reactor itself. One of skill in the art would generally recognize methods and apparatus suitable for such plasma treatment.

Depending on the particular process parameters, deposition may take place for a varying length of time. Generally, deposition may be allowed to continue as long as desired or necessary to produce a film with the necessary properties. Typical film thicknesses may vary from several hundred angstroms to several hundreds of microns, depending on the specific deposition process. The deposition process may also be performed as many times as necessary to obtain the desired film.

In some embodiments, the temperature and the pressure within the reactor are held at conditions suitable for ALD or CVD depositions. For instance, the pressure in the reactor may be held between about 1 Pa and about 10⁵ Pa, or preferably between about 25 Pa and 10³ Pa, as required per the deposition parameters. Likewise, the temperature in the reactor may be held between about 100° C. and about 500° C., preferably between about 150° C. and about 350° C.

In some embodiments, the precursor vapor solution and the reaction gas, may be pulsed sequentially or simultaneously (e.g. pulsed CVD) into the reactor. Each pulse of precursor may last for a time period ranging from about 0.01 seconds to about 10 seconds, alternatively from about 0.3 seconds to about 3 seconds, alternatively from about 0.5 seconds to about 2 seconds. In another embodiment, the reaction gas, may also be pulsed into the reactor. In such embodiments, the pulse of each gas may last for a time period ranging from about 0.01 seconds to about 10 seconds, alternatively from about 0.3 seconds to about 3 seconds, alternatively from about 0.5 seconds to about 2 seconds.

### Examples

The following non-limiting examples are provided to further illustrate embodiments of the invention. However, the examples are not intended to be all inclusive and are not intended to limit the scope of the inventions described herein.

### Example 1

### Removal of Adduct from Sr(iPr₃Cp)₂ (THF)₂ with Mesitylene

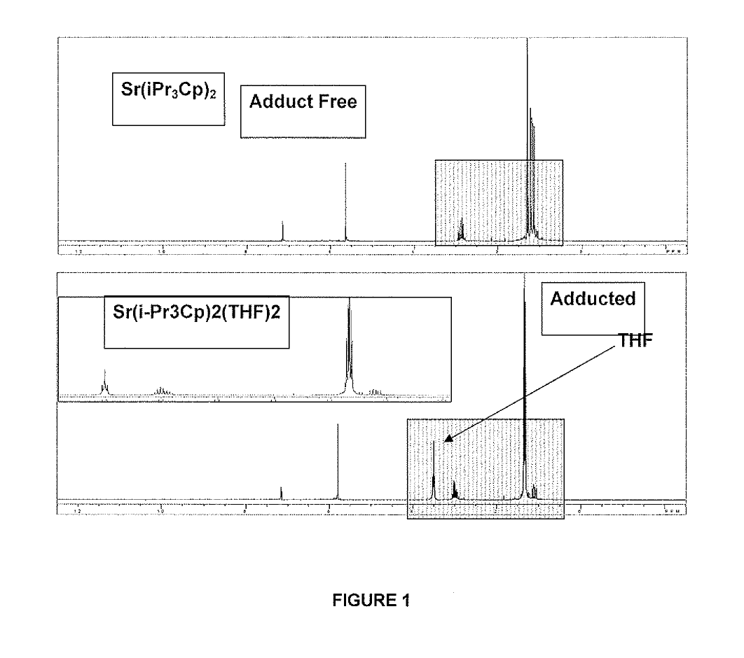

500 g of Sr(iPr₃Cp)₂(THF)₂ and 2000 ml of dried and O₂ free mesitylene were added in a 3 L flask with short path distillation setup under N₂. The mesitylene was distilled. The resulting liquid was transferred to 1 L flask with a fractional vacuum distillation setup. From this, 370 g main fraction of Sr(iPr₃Cp)₂ were collected at 140° C. and 0.02 torr. NMR analysis was performed for the initial Sr(iPr₃Cp)₂(THF)₂, as well for the resulting Sr(iPr₃Cp)₂, the results of which are shown in FIG. 1.

### Example 2

### Removal of Adduct from Ba(iPr₃Cp)₂(DME) with Mesitylene

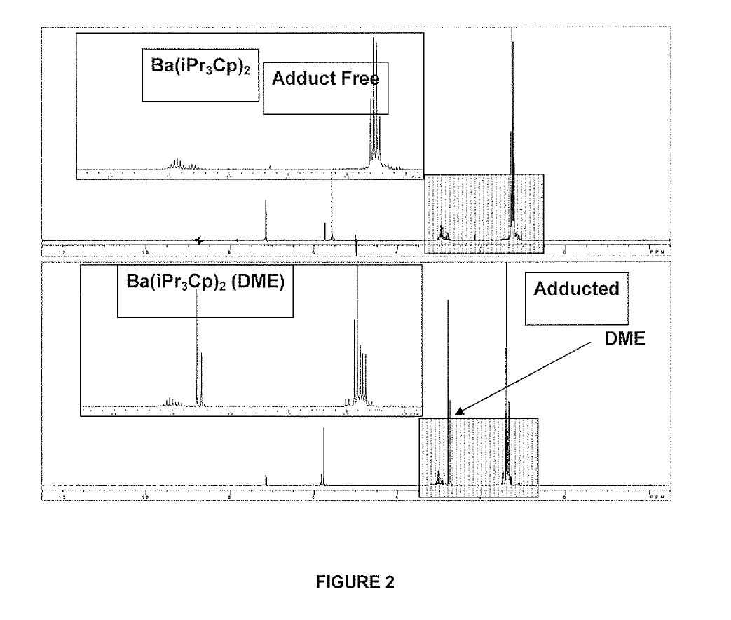

10 g of Ba(iPr₃Cp)₂(DME) and 50 ml of dried and O₂ free mesitylene were added in a 100 ml flask with short path distillation setup under N₂. The mesitylene was distilled. The resulting liquid was transferred to a 50 ml vacuum sublimation system. The solvent was then removed by vacuum. From this, 5.5 g of solid Ba(iPr₃Cp)₂ was collected. NMR analysis was performed for the initial Ba(iPr₃Cp)₂(DME), as well as for the resulting Ba(iPr₃Cp)₂, the results of which are shown in FIG. 2.

### Example 3

### Removal of Adduct from Ba(iPr₃Cp)₂(THF)₂ with Mesitylene

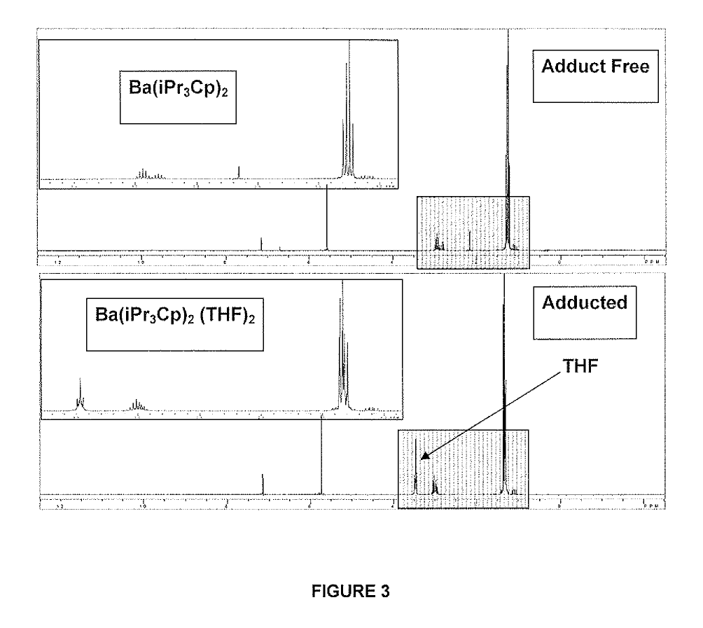

100 g of Ba(iPr₃Cp)₂(THF)₂ and 500 ml of dried and O₂ free mesitylene were added in a 1 L flask with short path distillation setup under N2. The mesitylene was distilled. The resulting liquid was transferred to a 500 ml vacuum sublimation system. The solvent was then removed by vacuum. From this, 65 g of solid Ba(iPr₃Cp)₂ was collected. NMR analysis was performed for the initial Ba(iPr₃Cp)₂(THF)₂, as well as for the resulting Ba(iPr₃Cp)₂, the results of which are shown in FIG. 3.

While embodiments of this invention have been shown and described, modifications thereof can be made by one skilled in the art without departing from the spirit or teaching of this invention. The embodiments described herein are exemplary only and not limiting. Many variations and modifications of the composition and method are possible and within the scope of the invention. Accordingly the scope of protection is not limited to the embodiments described herein, but is only limited by the claims which follow, the scope of which shall include all equivalents of the subject matter of the claims.

What is claimed is:

1. A method for providing a metal containing precursor substantially free of any adduct, comprising:
a) providing an adducted metal containing precursor of the general formula:
M(YₙCp)ₘ(X)ₐ(A)ₛ (I)
wherein:
1) M is an alkaline earth metal;
2) Cp is the cyclopentadienyl ligand;
3) Y is a C1-C6 alkyl group;
4) X is at least one ligand selected from the group consisting of: a C1-C6 alkyl group substituted cyclopentadienyl ligand; a dialkyl amide; an alkoxide; a halogen; and tetramethylheptadionate;
5) A is a Lewis base adduct; and
6) n is an integer such that 1≦n≦5, m is an integer such that 0 ≦m≦2, a is an integer such that 0≦a≦2, m+n=2, and s is an integer;
b) introducing at least one solvent to the precursor to form a solvent and precursor mixture;
c) distilling the solvent and precursor mixture to remove the adduct from the precursor; and
d) receiving from the distillation step a substantially adduct free precursor of the general formula:
M(YₙCP)ₘ(X)ₐ (II).

2. The method of claim 1, further comprising purifying the solvent and precursor mixture after the distilling step, wherein the purifying comprises either a vacuum distillation step or a sublimation step.

3. The method of claim 1, wherein the solvent and precursor mixture comprises a mixture with a ratio of solvent to precursor of at least about 10:1.

4. The method of claim 3, wherein the solvent and precursor mixture comprises a mixture with a ratio of solvent to precursor of at least about 5:1.

5. The method of claim 3, wherein the solvent and precursor mixture comprises a mixture with a ratio of solvent to precursor of at least about 3:1.

6. The method of claim 1, wherein the solvent comprises a solvent with a boiling point greater than that of the adduct, and less than that of the substantially adduct free precursor.

7. The method of claim 6, wherein the solvent comprises at least one member selected from the group consisting of: toluene; mesitylene; phenetol; octane; xylene; ethylbenzene; propylbenzene; ethyltoluene; ethoxybenzene; pyridine; and mixtures thereof.

8. The method of claim 1, wherein the Lewis Base adduct comprises at least one member selected from the group consisting of: tetrahydrofuran; dioxane; 1,2-diethoxyethane; 1,2-dimethoxyethane; dimethyl ether; diethyl ether and tetrahydropyranyl.

9. The method of claim 1, wherein the distilling step is a short path type distillation performed at about atmospheric pressure.

10. The method of claim 1, wherein M is an alkaline earth metal selected from strontium or barium.

11. The method of claim 1, wherein the adducted metal containing precursor comprises at least one member selected from the group consisting of:
Sr(iPr₃Cp)₂(THF)₂; Sr(iPr₃Cp)₂(THF)₂; Sr(iPr₃Cp)₂(DME); Sr(iPr₃Cp)₂(DME)₂;
Sr(iPr₃Cp)₂(diethylether); Sr(iPr₃Cp)₂(diethylether)₂; Sr(tBu₃Cp)₂(THF);
Sr(tBu₃Cp)₂(THF)₂; Sr(tBu₃Cp)₂(DME); Sr(tBu₃Cp)₂(DME)₂;
Sr(tBu₃Cp)₂(diethylether); Sr(tBu₃Cp)₂(diethylether)₂; Ba(iPr₃Cp)₂;
Ba(iPr₃Cp)₂(THF); Ba(iPr₃Cp)₂(THF)₂; Ba(iPr₃Cp)₂(DME); Ba(iPr₃Cp)₂(DME)₂;
Ba(iPr₃Cp)₂(diethylether); Ba(iPr₃Cp)₂(diethylether)₂; Ba(tBu₃Cp)₂;
Ba(tBu₃Cp)₂(THF); Ba(tBu₃Cp)₂(THF)₂; Ba(tBu₃Cp)₂(DME); Ba(tBu₃Cp)₂(DME)₂;
Ba(tBu₃Cp)₂(diethylether); and Ba(tBu₃Cp)₂(diethylether)₂; Sr(TMS₂N)₂(THF)₂;
Sr(TMS₂N)₂(DME)₂; Sr(Et₂N)₂(THF)₂; Sr(Et₂N)₂(DME)₂; Sr(Me₅Cp)(NTMS)(THF)₂;
Sr(Me₅Cp)(NTMS)(DME)₂; Sr(iPr₃Cp)(NTMS)(THF)₂; Sr(iPr₃Cp)(NTMS)(DME)₂;
Sr(tBu₃Cp)(NTMS)(THF)₂; Sr(tBu₃Cp)(NTMS)(DME)₂; Sr(MeₛCp)l(THF)₂;
Sr(Me₅Cp)l(DME)₂; Sr(iPr₃Cp)l(THF)₂; Sr(iPr₃Cp)l(DME)₂; Sr(tBu₃Cp)l(THF)₂;
Sr(tBu₃Cp)l(DME)₂; Sr(Me₅Cp)(Et₂N)(THF)₂; Sr(Me₅Cp)(Et₂N)(DME)₂;
Sr(iPr₃Cp)(Et₂N)(THF)₂; Sr(iPr₃Cp)(Et₂N)(DME)₂; Sr(tBu₃Cp)(Et₂N)(THF)₂;
Sr(tBu₃Cp)(Et₂N)(DME)₂; Sr(iPrO)₂(THF)₂; Sr(iPrO)₂(DME)₂; Sr(OMe)₂(THF)₂;
Sr(OMe)₂(DME)₂; Sr(Me₅Cp)(OMe)(THF)₂; Sr(Me₅Cp)(OMe)(DME)₂;
Sr(iPr₃Cp)(OMe)(THF)₂; Sr(iPr₃Cp)(OMe)(DME)₂; Sr(tBu₃Cp)(OMe)(THF)₂;
Sr(tBu₃Cp)(OMe)(DME)₂; Sr(Me₅Cp)(OEt)(THF)₂; Sr(Me₅Cp)(OEt)(DME)₂;
Sr(iPr₃Cp)(OEt)(THF)₂; Sr(iPr₃Cp)(OEt)(DME)₂; Sr(tBu₃Cp)(OEt)(THF)₂;
Sr(tBu₃Cp)(OEt)(DME)₂; Ba(TMS₂N)₂(THF)₂; Ba(TMS₂N)₂(DME)₂;
Ba(Et₂N)₂(THF)₂; Ba(Et₂N)₂(DME)₂; Ba(Me₅Cp)(NTMS)(THF)₂;
Ba(Me₅Cp)(NTMS)(DME)₂; Ba(iPr₃Cp)(NTMS)(THF)₂; Ba(iPr₃Cp)(NTMS)(DME)₂;
Ba(tBu₃Cp)(NTMS)(THF)₂; Ba(tBu₃Cp)(NTMS)(DME)₂; Ba(Me₅Cp)l(THF)₂;
Ba(Me₅Cp)l(DME)₂; Ba(iPr₃Cp)l(THF)₂; Ba(iPr₃Cp)l(DME)₂; Ba(tBu₃Cp)l(THF)₂;
Ba(tBu₃Cp)l(DME)₂; Ba(Me₅Cp)(Et₂N)(THF)₂; Ba(Me₅Cp)(Et₂N)(DME)₂;
Ba(iPr₃Cp)(Et₂N)(THF)₂; Ba(iPr₃Cp)(Et₂N)(DME)₂; Ba(tBu₃Cp)(Et₂N)(THF)₂;
Ba(tBu₃Cp)(Et₂N)(DME)₂; Ba(iPrO)₂(THF)₂; Ba(iPrO)₂(DME)₂; Ba(OMe)₂(THF)₂;
Ba(OMe)₂(DME)₂; Ba(Me₅Cp)(OMe)(THF)₂; Ba(Me₅Cp)(OMe)(DME)₂;
Ba(iPr₃Cp)(OMe)(THF)₂; Ba(iPr₃Cp)(OMe)(DME)₂; Ba(tBu₃Cp)(OMe)(THF)₂;
Ba(tBu₃Cp)(OMe)(DME)₂; Ba(Me₅Cp)(OEt)(THF)₂; Ba(Me₅Cp)(OEt)(DME)₂;
Ba(iPr₃Cp)(OEt)(THF)₂; Ba(iPr₃Cp)(OEt(DME)₂; Ba(tBu₃Cp)(OEt)(THF)₂; and
Ba(tBu₃Cp)(OEt)(DME)₂.

12. A method of forming a metal-containing film on a substrate, comprising:
a) providing a reactor and at least one substrate disposed therein;
b) providing an adducted metal containing precursor of the general formula:
M(YₙCp)ₘ(X)ₐ(A)ₛ(I)
wherein:
1) M is an alkaline earth metal;
2) Cp is the cyclopentadienyl ligand;
3) Y is a C1-C6 alkyl group;
4) X is at least one ligand selected from the group consisting of: a C1-C6 alkyl group substituted cyclopentadienyl ligand; a dialkyl amide; an alkoxide; a halogen; and tetramethylheptadionate;
5) A is a Lewis base adduct; and
6) n is an integer such that 1≦n≦5, m is an integer such that 0≦m≦2, a is an integer such that 0≦a≦2, m+n=2, and s is an integer;
c) introducing at least one solvent to the precursor to form a solvent and precursor mixture;
d) distilling the solvent and precursor mixture to remove the adduct from the precursor;
e) receiving from the distillation step a substantially adduct free precursor of the general formula:
M(YₙCp)ₘ(X)ₐ (II);
f) introducing the substantially adduct free precursor into the reactor;
g) maintaining the reactor at a temperature of at least 100° C.; and
h) contacting the precursor with the substrate to form a metal-containing film.
